(19) United States
(12) Patent Application Publication
(10) Pub. No.: US 2007/0004216 A1
(43) Pub. Date: Jan. 4, 2007

(54) Formation of assemblies with a diamond heat spreader

(76) Inventors: Chuan Hu, Chandler, AZ (US); Richard D. Emery, West Hartford, CT (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/173,834

(22) Filed: Jun. 30, 2005

(51) Int. Cl. H01L 21/302

(52) U.S. Cl. 438/713; 257/E23.103; 257/E23.111

(57) ABSTRACT

Electronic assemblies and methods for forming assemblies are described. One method of forming a semiconductor device includes providing a support substrate and forming a diamond layer on the support substrate. The diamond layer is detached from the support substrate and diced into a plurality of diamond heat spreader bodies. A material comprising a metal is formed on a first diamond heat spreader body of the plurality of diamond heat spreader bodies. A die is positioned on the first diamond heat spreader body so that the material comprising a metal is between the die and the first diamond heat spreader body. The method also includes heating the material comprising a metal and coupling the die to the first diamond heat spreader body. After the coupling the die to the first diamond heat spreader body, the method also includes coupling the die to a substrate, wherein the die is positioned between the first diamond heat spreader body and the substrate. Other embodiments are described and claimed.

### RELATED ART

Integrated circuits are generally formed on semiconductor wafers formed from materials such as silicon. The semiconductor wafers are processed to form various electronic devices thereon. The wafers are diced into semiconductor chips, which may then be attached to a package substrate using a variety of known methods. In one known method for attaching die to a substrate, the die may have solder bump contacts that are electrically coupled to the integrated circuit. The solder bump contacts extend onto the contact pads of a package substrate, and are typically attached in a thermal reflow process. Electronic signals may be provided through the solder bump contacts to and from the integrated circuit.

Operation of the integrated circuit generates heat in the device. As the circuit density increases and operates at increased clock frequencies and/or higher power levels, the amount of heat generated may rise to levels that are unacceptable unless some of the heat can be removed from the device. Heat is conducted to a surface of the die, and should be conducted or convected away to maintain the temperature of the integrated circuit below a predetermined level for purposes of maintaining functional integrity of the integrated circuit.

One way to conduct heat from an integrated circuit die is through the use of a heat spreader, which may be positioned above the die and thermally coupled to the die through a thermal interface material. Typically, copper has been used as the material for the heat spreader. Materials such as certain solders and adhesives have been used as thermal interface materials, allowing heat transfer between the die and the heat spreader, and allowing mechanical coupling to couple the heat spreader to the die. However, due to different thermal expansion characteristics of the various layers (die, thermal interface material, heat spreader), which are typically formed from different materials, the mechanical coupling of the die and heat spreader can be problematic. As a means for solving this problem, thermal interface materials including polymers have been used, the compliant nature of the polymer tending to minimize the effects of thermal expansion mismatch. However, polymer thermal interface materials generally have a poor intrinsic thermal conductivity (less than 10 W/m K), and are formed relatively thick (thicker than 1 mil) in order to absorb the thermal expansion mismatch between the different layers. This results in a significant degradation in the thermal performance of the system. As a result, a better thermal solution is needed.

### BRIEF DESCRIPTION OF THE DRAWINGS

Embodiments are described by way of example, with reference to the accompanying drawings, which are not drawn to scale, wherein:

FIG. 1 illustrates an electronic assembly including a substrate, die, heat spreader, thermal interface material, and heat sink, in accordance with certain embodiments;

FIG. 2 illustrates a step including forming a diamond layer in accordance with certain embodiments;

FIG. 3 illustrates a step including polishing the diamond layer of FIG. 2, in accordance with certain embodiments;

FIG. 4 illustrates the positioning for dicing the diamond layer of FIG. 3 into heat spreader bodies in accordance with certain embodiments;

FIG. 5 illustrates the positioning of a diamond heat spreader on a die with a thermal interface material therebetween in accordance with certain embodiments;

FIG. 6 illustrates an electronic assembly including a substrate, die, heat spreader, thermal interface material, and sealant, in accordance with certain embodiments;

FIG. 7 illustrates a die including a metallurgical layer thereon in accordance with certain embodiments;

FIG. 8 illustrates a heat spreader with a layer thereon for forming a thermal interface layer in accordance with certain embodiments;

FIG. 9 illustrates a heat spreader and die with a thermal interface material therebetween in accordance with certain embodiments;

FIG. 10 illustrates a flow chart for forming an electronic assembly in accordance with certain embodiments; and

FIG. 11 illustrates one embodiment of a computing environment in which aspects of the description provided herein are embodied.

### DETAILED DESCRIPTION

Certain embodiments relate to electronic assemblies and the formation of electronic assemblies including a diamond heat spreader coupled to a thin die through a thermal interface material. Diamond is an advantageous material for thermal performance because it has a substantially higher thermal conductivity than copper or silicon.

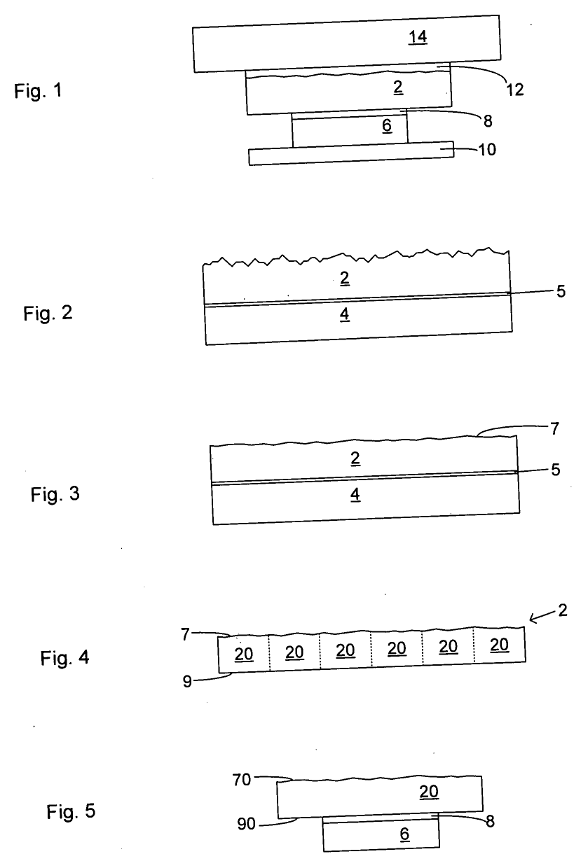

FIG. 1 illustrates a first embodiment including a heat spreader 2 formed from diamond that is coupled to a die 6 through a thermal interface material layer 8. The assembly also includes a substrate 10 to which the die 6 is coupled. The assembly also includes a heat sink 14, to which the heat spreader 2 is coupled through a thermal interface material layer 12.

FIGS. 2-5 illustrate certain aspects of a method for forming the assembly of FIG. 1.

As seen in FIG. 2, a diamond layer 2 is formed on a support substrate 4. The support substrate may be formed from a variety of materials, for example, single crystal silicon, polycrystalline silicon, amorphous silicon, chemical vapor deposited diamond, or molybdenum. Certain types of a thin layer 5 may in certain embodiments be formed in or on the surface of the support substrate 4. For example, the thin layer 5 may be a thin porous silica coating (approximately 0.5 μm) deposited on the support substrate 4 in order to facilitate easier removal of the diamond layer 2 from the support substrate 4. Alternatively, instead of a coating, a surface treatment such as hydrogen implantation may be carried out on the support substrate 4 to facilitate the removal of the diamond layer 2.

The diamond layer 2 may be formed using a variety of suitable processes, for example, chemical vapor deposition (CVD) and physical vapor deposition (PVD). One example of a CVD process includes a hot filament microwave plasma process at about 800-1200° C. While the thickness of the diamond layer 2 may be varied depending on a number of factors, including, but not limited to, the diamond layer formation process and the size of the die to be cooled, in certain embodiments, the diamond layer 2 is formed to have a thickness in the range from approximately 300 μm to approximately 3000 μm thick. Certain preferred embodiments have a thickness in the range of approximately 300 μm to approximately 600 μm.

As illustrated in FIG. 3, the upper surface 7 of diamond layer 2 is polished to a desired smoothness. Then, as illustrated in FIG. 4, the diamond layer 2 is separated from the support substrate 10. The separation may be carried out using a variety of suitable techniques, including, but not limited to, cleaving, and the use of a liquid jet such as a water jet. The separation method (e.g. cleaving, etc.) is preferably chosen to yield a substantially smooth surface 9 on the diamond layer 2. After the diamond layer 2 is separated from the support substrate 4, if an interface layer such as SiO₂ was used to facilitate removal of the diamond layer 2, then any remaining interface layer on the diamond layer 2 may be cleaned or polished off. The diamond layer 2 may, depending on its dimensions, then be diced (at the hatched lines in FIG. 4) into smaller bodies having proper dimensions to be used as heat spreaders 20.

As illustrated in FIG. 5, the individual heat spreader 20 includes a polished surface 70 (which was part of upper surface 7 of the diamond layer 2) and a smooth surface 90 (which was part of smooth surface 9 on the diamond layer 2). The smooth surface 90 of the diamond heat spreader 20 is bonded to a die 6 through a thermal interface layer 8. The die 6 may in certain embodiments be thinned to a thickness ranging from approximately 25 μm to approximately 150 μm, with certain embodiments being about 50 μm thick. Such a die may be formed by starting with a die having a greater thickness and then thinning the die using a suitable method. The thermal interface layer 8 may be formed from a material including a metal, and in certain embodiments preferably comprises a thin intermetallic solder formed to have a thickness ranging from approximately 5 μm to approximately 20 μm.

The polished surface 70 of the diamond heat spreader 20 may then be coupled to a heat sink 14 through a second thermal interface layer 12, yielding the structure illustrated in FIG. 1. The second thermal interface layer 12 may in certain embodiments be a solder or a phase change polymer material (for example, an epoxy).

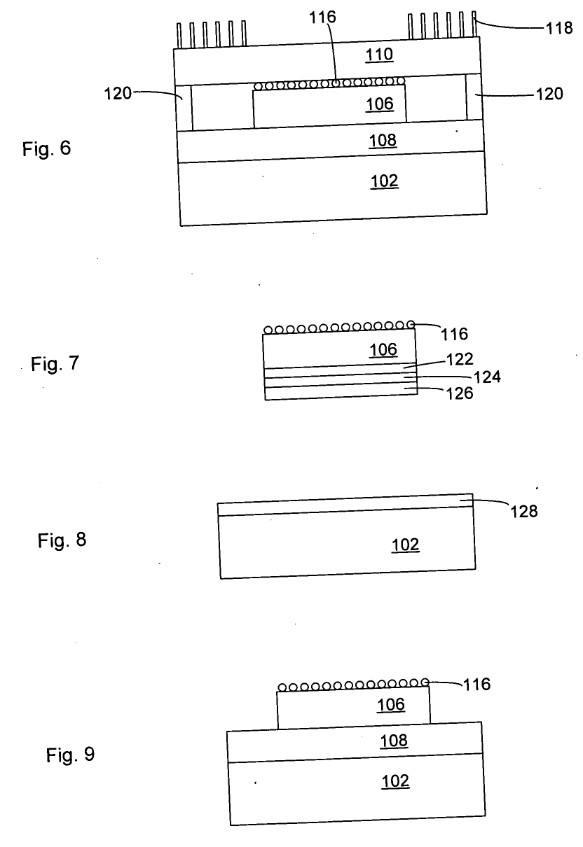

FIG. 6 illustrates another embodiment including a heat spreader 102 formed from diamond that is coupled to a die 106 through a thermal interface material layer 108. The assembly also includes a substrate 110 to which the die 106 is coupled. The substrate 110 may include pins 118 or other types of connections for coupling the substrate to a device such as, for example, a motherboard. Certain aspects of this embodiment are in some ways similar to certain aspects of the embodiment illustrated in FIG. 1.

In various embodiments, the die and heat spreader may have different width dimensions. For example, as seen in FIG. 6, the die 106 has a smaller width dimension than the heat spreader 102. It is also possible to have a die having a larger width dimension than the heat spreader. An example of an application in which the heat spreader has a smaller width dimension than the die is where only a portion of a die generates excessive heat and positioning a heat spreader on only that portion of the die provides adequate performance.

FIGS. 7-9 illustrate certain aspects of a method for forming the assembly of FIG. 6. FIG. 7 illustrates a thinned die 106 that may, for example, be formed from silicon. In certain embodiments the thinned die 106 has a thickness in the range of about 25-150 μm, with a preferred thickness of about 50 μm. A number of metallurgical layers may be formed on the die 106. These layers may include one or more of a diffusion barrier layer, a layer to form an intermetallic, and a wetting layer. As seen in the FIG. 7, layer 122 is a diffusion barrier layer formed to prevent interactions between the die 106 (which may be formed from silicon) and other materials. In certain embodiments, the layer 122 is formed from Ti (titanium). The layer 122 may also act as an adhesion layer. Layer 124 may be formed directly on the die, with layer 122 being positioned between layer 124 and the die 106. Layer 124 is formed from a material that will form an intermetallic during subsequent processing. In certain embodiments, the layer 124 is formed from NiV (nickel-vanadium). Layer 126 is formed on the die, with layers 122 and 124 being positioned between layer 126 and the die 106. Layer 126 is formed from a material that will act as a wetting layer to promote bonding with the layer of material 128 on the heat spreader 102 that will be used to form the thermal interface material 108. In certain embodiments, the layer 126 is formed from Au (gold). In one embodiment, the layer 122 is a Ti layer having a thickness of about 100 nm, the layer 124 is a NiV layer having a thickness of about 360 nm, and the layer 126 is a Au layer having a thickness of about 100 nm.

FIG. 8 illustrates a diamond heat spreader 102 that may be formed in a similar manner as described above for heat spreader 20. A layer 128 formed from, for example, a material comprising a metal, such as hard solder alloy or intermetallic solder alloy, is deposited on a surface of the diamond heat spreader 102 that will be coupled to the die 106. In certain embodiments, the layer 128 is formed from a gold/tin intermetallic solder alloy having about 80 weight percent Au and about 20 weight percent Sn (tin) and formed to have a thickness in the range of approximately 5 μm to approximately 20 μm. The diamond heat spreader 102 with the layer 128 thereon and the die 106 with the layers 122, 124, and 126 thereon are physically pressed together with a suitable bonding pressure and heated to a suitable bonding temperature. In certain embodiments, the pressed together structure is loaded into a reflow oven purged with an inert gas or other protective gas such as formic acid gas and heated to a bonding temperature of about 280 to 310° C., where the solder material on the heat spreader melts and wets the backside of the die. The wetting layer 126 is depleted and an intermetallic is formed between the AuSn solder of layer 128 and NiV of layer 124 to form the thermal interface layer 108. At least a portion of the diffusion barrier layer 122 may still be present between the die 106 and the thermal interface layer 108.

The structure illustrated in FIG. 9 may then be attached to a substrate 110 as illustrated in FIG. 6, to form a package. In certain embodiments, solder bumps 116 are used to couple the die to the substrate 110. Other connections may also be used. Certain embodiments may also provide a sealant 120 positioned in one or more regions between the substrate 110 and thermal interface material 108. The sealant may be formed from a variety of materials such as, for example, an epoxy.

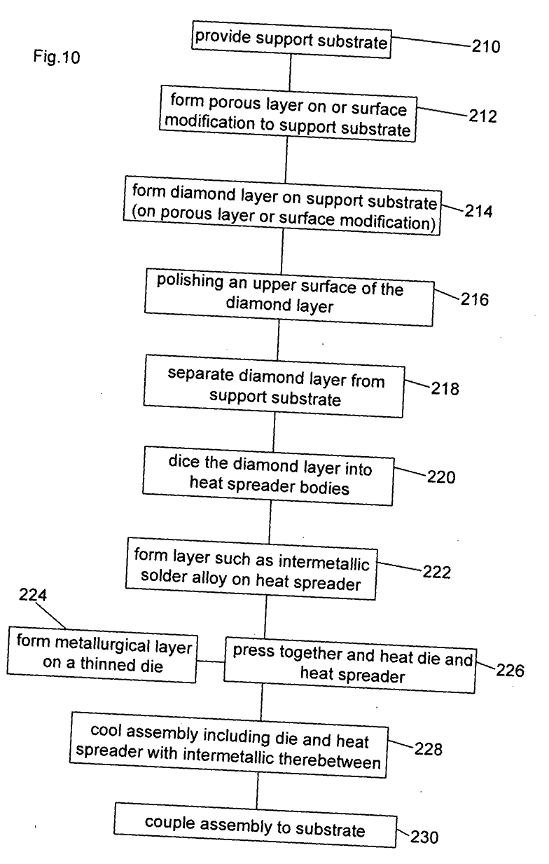

FIG. 10 illustrates in flow chart form methods for forming an assembly including a semiconductor die, a diamond heat spreader coupled to the die through a thermal interface material, and a substrate coupled to the die. Box 210 is providing a support substrate. Box 212 is either (1) forming a porous layer (such as SiO₂) on, or (2) performing a surface modification (e.g. hydrogen implantation) of, the support substrate. Box 214 is forming a diamond layer (such as CVD diamond) on the support substrate having the porous layer or surface modification. Box 216 is polishing an upper surface of the diamond layer. Box 218 is separating the diamond layer from the support substrate. Box 220 is dicing the diamond layer into a plurality of smaller bodies sized to be used as diamond heat spreaders. Box 222 is forming a layer, for example, an intermetallic solder alloy, on a diamond heat spreader.

Box 224 is forming a metallurgical layer on a thinned die. The metallurgical layer may include one or more layers such as a diffusion barrier layer, a layer to form an intermetallic, and a wetting layer.

Box 226 is pressing together the diamond heat spreader and the die and heating to form an intermetallic layer that couples the heat spreader to the die. Box 228 is cooling the assembly. Box 230 is coupling the assembly to a substrate.

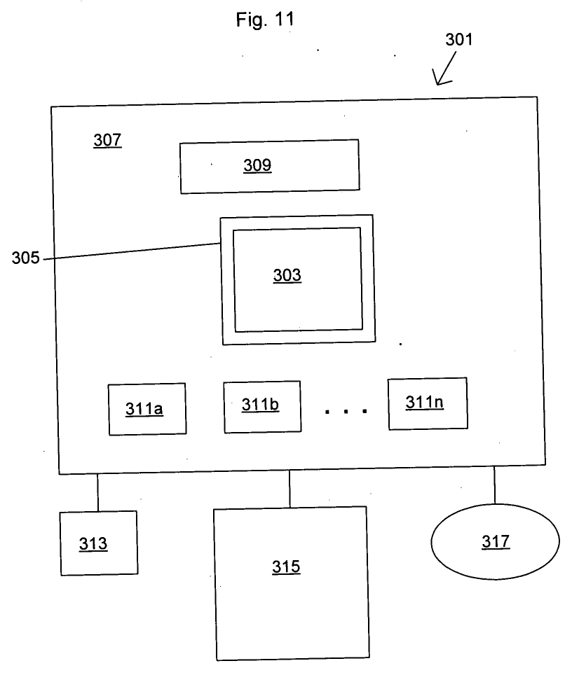

FIG. 11 schematically illustrates one example of a computing environment in which aspects of described embodiments may be embodied. The computing environment includes a computer 301 including at least one central processing unit (CPU) 303. The CPU 303, also referred to as a microprocessor, may be attached to an integrated circuit package 305, which is then coupled to a printed circuit board 307, which in this embodiment, is a motherboard. The integrated circuit package 305 is an example of an electronic assembly in accordance with the embodiments discussed above and shown in FIGS. 1-9.

The computer 301 further may further include memory 309 and one or more controllers 311a, 311b . . . 311n, which are also disposed on the motherboard 307. The motherboard 307 may be a single layer or multi-layered board which has a plurality of conductive lines that provide communication between the circuits in the package 305 and other components mounted to the board 307. Alternatively, one or more of the CPU 303, memory 309 and controllers 311a, 311b . . . 311n may be disposed on other cards such as daughter cards or expansion cards. The CPU 303, memory 309 and controllers 311a, 311b . . . 311n may each be seated in individual sockets or may be connected directly to a printed circuit board. A display 315 may also be included.

Any suitable operating system and various applications execute on the CPU 303 and reside in the memory 309. The content residing in memory 309 may be cached in accordance with known caching techniques. Programs and data in memory 309 may be swapped into storage 313 as part of memory management operations. The computer 301 may comprise any suitable computing device, such as a mainframe, server, personal computer, workstation, laptop, handheld computer, telephony device, network appliance, virtualization device, storage controller, network controller, etc.

The controllers 311a, 311b . . . 311n may include a system controller, peripheral controller, memory controller, hub controller, I/O bus controller, video controller, network controller, storage controller, etc. For example, a storage controller can control the reading of data from and the writing of data to the storage 313 in accordance with a storage protocol layer. The storage protocol of the layer may be any of a number of known storage protocols. Data being written to or read from the storage 313 may be cached in accordance with known caching techniques. A network controller can include one or more protocol layers to send and receive network packets to and from remote devices over a network 317. The network 317 may comprise a Local Area Network (LAN), the Internet, a Wide Area Network (WAN), Storage Area Network (SAN), etc. Embodiments may be configured to transmit data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

1. A method of forming a semiconductor device, comprising:
providing a support substrate;
forming a diamond layer on the support substrate;
detaching the diamond layer from the support substrate; and
dicing the diamond layer into a plurality of diamond heat spreader bodies;
forming a material comprising a metal on a first diamond heat spreader body of the plurality of diamond heat spreader bodies;
positioning a die on the first diamond heat spreader body so that the material comprising a metal is between the die and the first diamond heat spreader body;
applying heat to the material comprising a metal and coupling the die to the first diamond heat spreader body; and
after the coupling the die to the first diamond heat spreader body, coupling the die to a substrate, wherein the die is positioned between the first diamond heat spreader body and the substrate.

2. A method as in claim 1, further comprising, prior to the positioning the die on the first diamond heat spreader body, thinning the die to a thickness of no greater than 150 μm.

3. A method as in claim 1, wherein the first diamond heat spreader body is formed to have a thickness in the range of 300 μm to 3000 μm.

4. A method as in claim 1, further comprising forming the material comprising a metal on the first diamond heat spreader to have a thickness in the range of 5 μm to 20 μm.

5. A method as in claim 1, further comprising forming a plurality of metal layers on the die prior to positioning the die on the first diamond heat spreader body, and positioning the die with the plurality of metal layers on the first diamond heat spreader body so that the material comprising a metal and the plurality of metal layers are positioned between the die and the first diamond heat spreader.

6. A method as in claim 5, wherein the applying heat to the material comprising a metal and coupling the die to the first diamond heat spreader body further includes heating the plurality of metal layers and interacting the material comprising a metal with at least one of the plurality of metal layers to form an intermetallic material.

7. A method as in claim 5, wherein, after the heating, at least one of the plurality of metal layers and the material comprising a metal form a thermal interface material between the die and the first diamond heat spreader.

8. A method as in claim 5, further comprising forming the plurality of metal layers to include a nickel/vanadium layer and a gold layer, and forming the material comprising a metal to include a silver/tin solder alloy.

9. A method as in claim 5, further comprising selecting the material comprising a metal and at least one of the plurality of metal layers so that upon heating, an intermetallic material is formed.

10. A method as in claim 1, further comprising, prior to forming the diamond layer on the support substrate, treating the support substrate surface to facilitate removal of the subsequently formed diamond layer.

11. A method as in claim 1, further comprising, prior to the detaching the diamond layer from the support substrate, polishing a surface of the diamond layer.

12. A method as in claim 1, wherein the material comprising a metal comprises a solder.

13. A method as in claim 1, wherein the first diamond heat spreader body has a width that is different than that of the die.

14. A method as in claim 13, wherein the width of first diamond heat spreader body is greater than that of the die.

15. A method as in claim 13, wherein the width of first diamond heat spreader body is less than that of the die.

16. A method as in claim 1, wherein the first diamond heat spreader body is formed to have a thickness in the range of 300 μm to 600 μm.

17. A method of forming a semiconductor device, comprising:
providing a support substrate;
forming a diamond layer on the support substrate;
separating the diamond layer from the support substrate, wherein at least a portion of the separated diamond layer is adapted to be a diamond heat spreader;
coupling the diamond heat spreader from the separated diamond layer to a first surface of a semiconductor die through a thermal interface material, the thermal interface material comprising a metal;
after the coupling the diamond heat spreader to the first surface of the semiconductor die, coupling a second surface of the semiconductor die to a substrate, wherein the die is positioned between the thermal interface material and the substrate; and
wherein the at least a portion of the diamond heat spreader, the thermal interface material, and the substrate are each formed to have a larger width that that of the semiconductor die.

18. A method as in claim 17, further comprising, prior to the coupling the diamond heat spreader to a first surface of the semiconductor die, thinning the die to a thickness of no greater than 150 μm.

19. A method as in claim 17, wherein the diamond heat spreader is formed to have a thickness in the range of 300 μm to 3000 μm.

20. A method as in claim 17, wherein the material comprising a metal is formed on the diamond heat spreader to a thickness in the range of 5 μm to 20 μm.

21. A method as in claim 17, further comprising providing a sealant material positioned between the thermal interface material and the substrate, wherein a gap remains between the semiconductor die and the sealant material.

22. A method as in claim 17, wherein the diamond heat spreader is formed to have a thickness in the range of 300 μm to 600 μm.

23. A method of forming a semiconductor device, comprising:
providing a support substrate;
forming a diamond layer on the support substrate;
polishing a surface of the diamond layer;
detaching the diamond layer from the support substrate, the diamond layer including the polished surface and an unpolished surface;
dicing the diamond layer into a plurality of diamond heat spreader bodies each having a polished surface and an unpolished surface;
forming a material comprising a metal on the unpolished surface of a first diamond heat spreader body of the plurality of diamond heat spreader bodies;
positioning a die on the first diamond heat spreader body so that the material comprising a metal is between the die and the first diamond heat spreader body;
applying heat to the material comprising a metal and coupling the die to the first diamond heat spreader body;
after the coupling the die to the first diamond heat spreader body, coupling the die to a substrate, wherein the die is positioned between the first diamond heat spreader body and the substrate; and
after the coupling the die to the first diamond heat spreader body, coupling the polished surface of the first diamond heat spreader body to a heat sink through a second thermal interface material.

24. A method as in claim 23, further comprising, prior to the coupling the die to the first diamond heat spreader body, thinning the die to a thickness of no greater than 150 μm.

25. A method as in claim 24, wherein the first diamond heat spreader body is formed to have a thickness in the range of 300 μm to 600 μm.

26. A method as in claim 23, wherein the material comprising a metal comprises a solder alloy that is formed on the first diamond heat spreader body to a thickness in the range of 5 μm to 20 μm.
